(19) United States
(12) Patent Application Publication
(10) Pub. No.: US 2025/0301597 A1
(43) Pub. Date: Sep. 25, 2025

(54) Heat Dissipation Structure for Induction Hobs and Induction Hob

(71) Applicant: Guangdong Willing Technology Corporation, Huizhou (CN)

(72) Inventors: Jingnong Ye, Huizhou (CN); Shifa Luo, Huizhou (CN); Jiulong Wang, Huizhou (CN)

(21) Appl. No.: 18/748,194

(22) Filed: Jun. 20, 2024

(30) Foreign Application Priority Data
Mar. 22, 2024 (CN) 202420575305.4

(51) Int. Cl. H05K 7/20; H05K 5/02; H05K 5/03

(52) U.S. Cl. CPC H05K 7/20172; H05K 5/0208; H05K 5/0213; H05K 5/03; H05K 7/20145; H05K 7/2039

(57) ABSTRACT

Disclosed in the present disclosure is a heat dissipation structure for induction hobs and an induction hob, in which the heat dissipation structure includes a bottom housing for induction hobs, an interior of the bottom housing is flatly provided with a motherboard and an electromagnetic coil, and the electromagnetic coil is provided with at least two fans adjacent thereto. The side wall of the bottom housing is provided as a curved wall with a vent opening in the present disclosure, which effectively increases the area of the vent opening and thus improves the ventilation volume and ventilation efficiency. At least two fans are provided inside the bottom housing, so that the two fans may simultaneously perform the heat dissipation on the electromagnetic coil and the motherboard, which improves the utilization efficiency of the fans.

### CROSS REFERENCE TO RELATED APPLICATIONS

The present application claims the benefit of Chinese Patent Application No. 2024205753054 filed on Mar. 22, 2024, the contents of which are incorporated herein by reference in their entirety.

### FIELD

The present disclosure relates to the technical field of induction hobs and, particularly, to a heat dissipation structure for induction hobs.

### BACKGROUND

Induction hobs work on the principle of eddy current heating generated by electromagnetic induction. That is, a magnetic field is generated by passing a current through a coil, and when magnetic induction lines in the magnetic field pass through the bottom of an iron pan, the magnetic induction lines are cut, resulting in countless small eddy currents, which enables the iron atoms in the iron pan to rotate at high speed and generate collision friction to generate heat to directly heat up the food placed in the pan.

Since induction hobs heat the bottom of the pan directly by electromagnetic induction, it is usually necessary to install a heat dissipation structure on the induction hob in order to prevent the electronic components inside the induction hob from shortening the service life of the induction hob due to high temperatures. However, the induction hob on the market is not sufficiently rationalized due to the arrangement of the heat dissipation structure, resulting in a relatively thick induction hob, which is not easy to carry on a trip.

The aforementioned deficiencies of the prior art are: the induction hob on the market is not sufficiently rationalized due to the arrangement of the heat dissipation structure, resulting in a relatively thick induction hob, which is not easy to carry on a trip.

### SUMMARY

An objective of the present disclosure is to provide a heat dissipation structure for induction hobs, in order to solve the technical problem that the induction hobs on the market are not easy to carry on a trip due to insufficient rationalization of the arrangement of the heat dissipation structure, which results in a relatively thick induction hob.

To achieve the aforementioned objective, provided in the technical solutions of the present disclosure is a heat dissipation structure for induction hobs, including a bottom housing for induction hobs, in which a sidewall of the bottom housing is gradually extended outwardly inclined and concave inwardly into a curved wall from bottom to top, the curved wall being provided with a plurality of vent openings, an interior of the bottom housing is flatly provided with a motherboard and an electromagnetic coil, at least two fans are provided on a side of the electromagnetic coil, all fans are provided spaced apart around the electromagnetic coil, a side of the fans facing the electromagnetic coil is provided with a first opening for achieving heat dissipation of the electromagnetic coil, and the fans proximal to the motherboard are further provided with a second opening facing the motherboard for achieving heat dissipation of the motherboard.

Further, an interior of the bottom housing is provided with a control board, the motherboard, and the electromagnetic coil arranged sequentially along a length direction thereof, two fans are provided on a side of the electromagnetic coil, two fans are configured to be a first fan and a second fan, a second space for mounting the second fan is provided at an upper right corner of an inner side of the bottom housing, and a first space for mounting the first fan is provided between the control board and the electromagnetic coil.

Further, the motherboard is fixedly provided with a heat dissipation sheet arranged close to the second opening, and the vent opening is extended upwardly from a bottom of the curved wall to form a hole in a shape like a bar.

Further, an interior of the bottom housing is provided with a control board, the motherboard, and the electromagnetic coil arranged sequentially along a length direction thereof, two fans are provided on a side of the electromagnetic coil, two fans are configured to be a first fan and a second fan, a second space for mounting the second fan is provided at a corner of an inner side of the bottom housing, and a first space for mounting the first fan is provided between the control board and the electromagnetic coil.

Further, the bottom housing is fixedly provided with a first partition and a second partition extending vertically upwards, the first partition and the second partition divide an interior of the bottom housing into a cold-air zone and a hot-air zone, the first fan and the second fan are positioned in the cold-air zone, and the motherboard and the electromagnetic coil are positioned in the hot-air zone.

Further, the first partition is provided between the first fan and the second fan, the second partition is provided between the control board and the motherboard,
a side of an upper cover for induction hobs facing the bottom housing is fixedly provided with a third partition extending vertically downwards, a position of the third partition corresponds to those of the first partition and the second partition, and a bottom surface of the third partition is abutted against a bottom surface of the first partition and a top surface of the second partition when the upper cover is snap-fitted to the bottom housing, so as to separate the cold-air zone and the hot-air zone.

Further, a clearance is provided between a bottom of the electromagnetic coil and an inner bottom surface of the bottom housing.

Further, the vent opening comprises a first air inlet and a first air outlet, the first air inlet is provided at a front sidewall of the bottom housing, the first air outlet is provided at a rear sidewall of the bottom housing, and both the first opening and the second opening are provided in a direction facing the first air outlet.

Further, a right sidewall and/or a left sidewall of the bottom housing is fixedly provided with a retainment plate extending vertically upwards, the vent opening is further provided with a second air inlet and a second air outlet, both the second air inlet and the second air outlet are provided on the right sidewall or the left sidewall of the bottom housing, the retainment plate is provided between the second air inlet and the second air outlet so as to divide an interior of the bottom housing into a cold-air zone and a hot-air zone, the second air inlet is positioned in the cold-air zone, and the second air outlet is positioned in the hot-air zone.

Further, the retainment plate is close to one of the fans, and the retainment plate is extended from a sidewall of the bottom housing to the first opening of the fan close to the retainment plate, so that the fan is positioned in the cold-air zone.

Provided in the technical solutions of the present disclosure is further an induction hob, including an upper cover and the aforementioned heat dissipation structure, in which an inner periphery of the bottom housing is provided with a plurality of positioning columns extending vertically upwards, the positioning column is provided with a stepped hole with an opening facing upwards, a side of the upper cover facing the bottom housing is provided with a plurality of columns, and the plurality of columns is in interference fit with a plurality of the stepped holes.

In summary, a heat dissipation structure for induction hobs and an induction hob in the present disclosure have the following beneficial effects:

The side wall of the bottom housing is provided as a curved wall with a vent opening in the present disclosure, which effectively increases the area of the vent opening and thus improves the ventilation volume and ventilation efficiency of the vent opening. At least two fans are provided inside the bottom housing, so that the two fans may simultaneously perform the heat dissipation on the electromagnetic coil, which greatly improves the heat dissipation efficiency. One of the fans also takes into account being able to dissipate the heat of the motherboard, which improves the utilization efficiency of the fans. Also, since the sidewall of the bottom housing is a curved wall, the height of the housing is effectively reduced while ensuring that the ventilation area of the vent opening is not reduced. Moreover, the flat setting of the motherboard and electromagnetic coil in the bottom housing, as well as two fans positioned in the periphery of the electromagnetic coil, may effectively reduce the thickness of the housing, which all enable the induction hob to achieve ultra-thin design, which is convenient for the user to carry around during outings, and greatly improves the competitiveness of the product.

### BRIEF DESCRIPTION OF THE DRAWINGS

FIG. 1 is a schematic structural diagram in a perspective view of the present invention removing the front panel and the upper cover;

FIG. 2 is a schematic structural diagram in a perspective view of FIG. 1 with the upper cover;

FIG. 3 is a schematic structural diagram in a perspective view of FIG. 1 removing the control board, motherboard, and the heat dissipation sheet;

FIG. 4 is a schematic structural diagram in a perspective view of the bottom housing in the present invention;

FIG. 5 is a schematic structural diagram in a perspective view of the upper cover in the present invention;

FIG. 6 is a schematic structural diagram in a perspective view of the present invention;

FIG. 7 is a schematic structural diagram in a bottom view of FIG. 6;

FIG. 8 is a schematic structural diagram in a front view of the present invention;

Labels: 1 front panel; 2 upper cover; 201 column; 202 third partition; 3 bottom housing; 301 retainment plate; 302 first threaded column; 303 second threaded column; 304 positioning column; 305 groove; 306 first partition; 307 second partition; 4 control board; 5 motherboard; 6 electromagnetic coil; 7 heat dissipation sheet; 8 first fan; 9 second fan; 10 first air inlet; 11 first air outlet; 12 second air inlet; 13 second air outlet; 14 power line.

### DETAILED DESCRIPTION OF THE EMBODIMENTS

The technical solutions in the embodiments of the present disclosure are clearly and completely described below in conjunction with the accompanying drawings of the present disclosure, but without limiting the scope of the present disclosure.

In the present disclosure, for better description, the following illustrations are made: the observer faces the accompanying FIG. 8 for observation, the left side of the observer is set to left, the right side of the observer is set to right, the front of the observer is set to front, the back of the observer is set to back, the top of the observer is set to top, and the bottom of the observer is set to bottom. It should be noted that the terms “front,” “back,” “left,” “right,” “center,” “top,” “bottom,” and the like are used in the text to indicate orientation or positional relationships based on the accompanying drawings only for the purpose of facilitating a clear description of the present disclosure and are not intended to indicate or imply that the structures or parts referred to necessarily have a particular orientation or are constructed in a particular orientation and, therefore, are not to be construed as a limitation of the present disclosure. In addition, the related terms “first”, “second”, “third” and “fourth”, if any, are used only for purposes of clarity or simplicity of description and are not to be construed as indicating or implying relative importance or quantity.

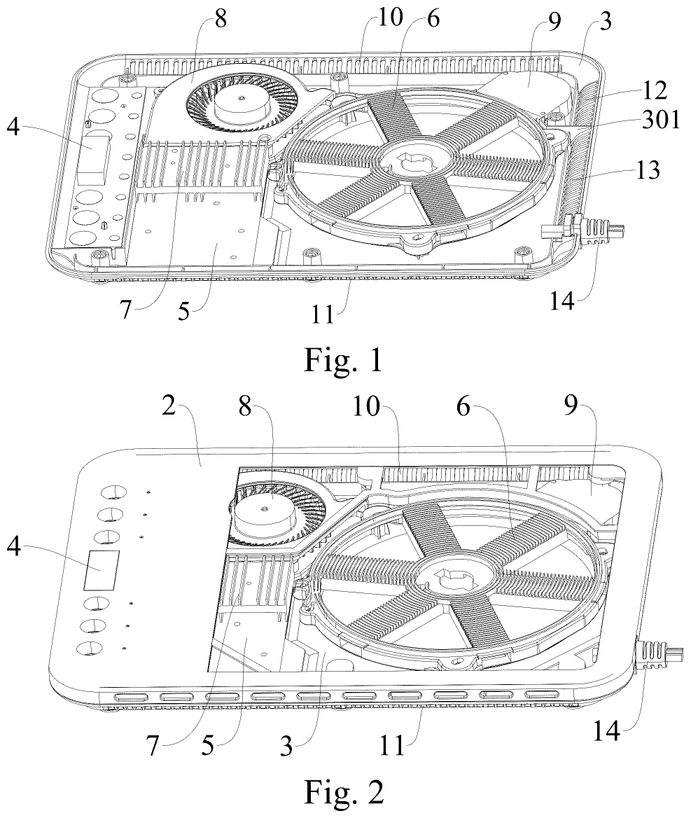

Referring to FIGS. 1-8, provided in the present embodiment is a heat dissipation structure for induction hobs, which is applied to induction hobs. Referring to FIGS. 6-8, the induction hob includes a front panel 1, an upper cover 2, and a bottom housing 3 sequentially from top to bottom. A sidewall of the bottom housing 3 is gradually extended outwardly inclined and concave inwardly into a curved wall from bottom to top, the curved wall is provided with a plurality of vent openings, all vent openings are arranged side by side, and the vent openings are extended upwardly from a bottom of the curved wall to form holes in a shape like a bar to maximize areas of the vent openings. Since the sidewall of the bottom housing 3 is a curved wall, the height of the bottom housing 3 is effectively reduced while ensuring that the ventilation area of the vent opening is not reduced. That is, it may effectively reduce the thickness of the bottom housing 3, which all enable the induction hob to achieve ultra-thin design

Referring to FIGS. 1-2, the heat dissipation structure in the present embodiment includes a bottom housing 3, in which an interior of the bottom housing 3 is provided with a control board 4, a motherboard 5, and an electromagnetic coil 6 arranged sequentially from left to right, and at least two fans are provided on a side of the electromagnetic coil 6. In the present embodiment, two fans are provided on a side of the electromagnetic coil 6, two fans are provided spaced apart around the electromagnetic coil 6, and a side of the fans facing the electromagnetic coil 6 is provided with a first opening for achieving heat dissipation of the electromagnetic coil 6; the motherboard 5 is fixedly provided with a heat dissipation sheet 7, the fan proximal to the motherboard 5 is further provided with a second opening facing the motherboard 5, and the heat dissipation sheet 7 is provided close to the second opening, which achieves heat dissipation of the motherboard 5.

The heat dissipation structure of the present disclosure makes good use of the internal space of the bottom housing 3. Since the sidewall of the bottom housing 3 is set as a curved wall with vent openings, the height of the bottom housing 3 is effectively reduced while ensuring that the ventilation area of the vent opening is not reduced. That is, it may effectively reduce the thickness of the bottom housing 3, which achieves the ultra-thin design of the bottom housing 3. At least two fans are provided inside the bottom housing 3, so that the two fans may simultaneously perform the heat dissipation on the electromagnetic coil 6, which greatly improves the heat dissipation efficiency. One of the fans also takes into account being able to dissipate the heat of the motherboard 5, which improves the utilization efficiency of the fans. Also, the flat setting of the motherboard 5 and electromagnetic coil 6 in the bottom housing 3, as well as two fans positioned in the periphery of the electromagnetic coil 6, may effectively reduce the thickness of the bottom housing 3, which all enable the induction hob to achieve ultra-thin design, which is convenient for the user to carry around during outings, and greatly improves the competitiveness of the product.

Specifically, referring to FIGS. 1-2, two fans are configured to be a first fan 8 and a second fan 9, a second space for mounting the second fan 9 is provided at a corner of an upper right inner side of the bottom housing, and a first space for mounting the first fan 8 is provided between the control board 4 and the electromagnetic coil 6. Effect: By setting the first fan 8 and the second fan 9 at the left and right ends of the bottom housing 3 respectively, it is conducive to diverting and dispersing the heat inside the bottom housing 3, so that the heat dissipation efficiency may be greatly improved.

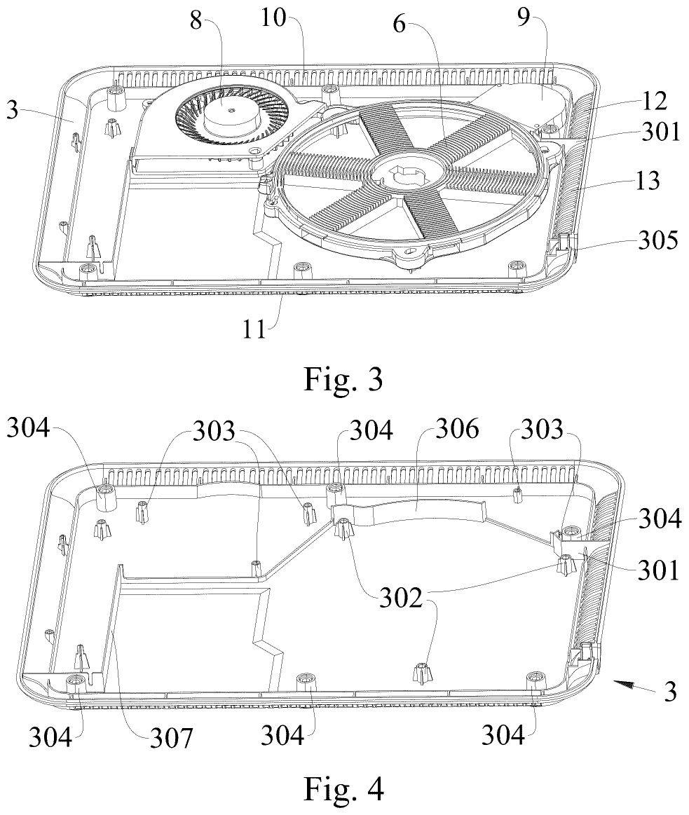

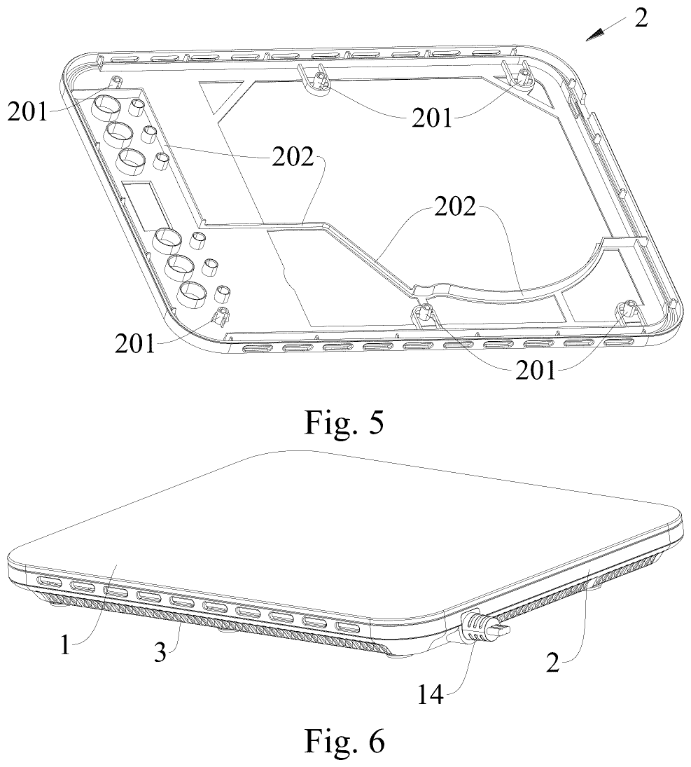

Specifically, referring to FIGS. 3-4, the bottom housing 3 is fixedly provided with a first partition 306 and a second partition 307 extending vertically upwards, the first partition 306 is provided between the first fan 8 and the second fan 9, and the second partition 307 is provided between the control board 4 and the motherboard 5. Referring to FIG. 5, a side of an upper cover 2 facing the bottom housing 3 is fixedly provided with a third partition 202 extending vertically downwards, and a position of the third partition 202 corresponds to those of the first partition 306 and the second partition 307, so as to separate the cold-air zone and the hot-air zone. That is, the first partition 306 and the second partition 307 divide an interior of the bottom housing 3 into a cold-air zone and a hot-air zone, the first fan 8, the second fan 9 and the control board 4 are positioned in the cold-air zone, and the motherboard 5 and the electromagnetic coil 6 are positioned in the hot-air zone.

In practice, by setting the first partition 306, the second partition 307, and the third partition 202, the present invention ensures that the hot air does not circle around and stays in the interior of the bottom housing 3. The motherboard 5 and the electromagnetic coil 6 are heat generating elements. The bottom housing 3 divides the area where the control board 4 and the two fans are provided into a cold-air zone, and the area where the motherboard 5 and the electromagnetic coil 6 are provided into a hot-air zone by means of the first partition 306, the second partition 307, and the third partition 202. Cold air enters the interior of the bottom housing 3 through the vent opening on a side of the curved wall close to the fan, and is transformed into hot air after sufficiently contacting the motherboard 5 and the electromagnetic coil 6. Shortly thereafter, the hot air leaves the bottom housing 3 through the vent opening on the other side of the curved wall, so that heat dissipation of the electromagnetic coil 6 and the motherboard 5 may be achieved.

Specifically, a clearance is provided between a bottom of the electromagnetic coil 6 and an inner bottom surface of the bottom housing 3, so as to facilitate the heat dissipation of the electromagnetic coil 6. In practice, a certain clearance is provided between the bottom of the electromagnetic coil 6 and the bottom housing 3, which enables the air entering from the outside to flow through the clearance to carry out the heat at the bottom of the electromagnetic coil 6.

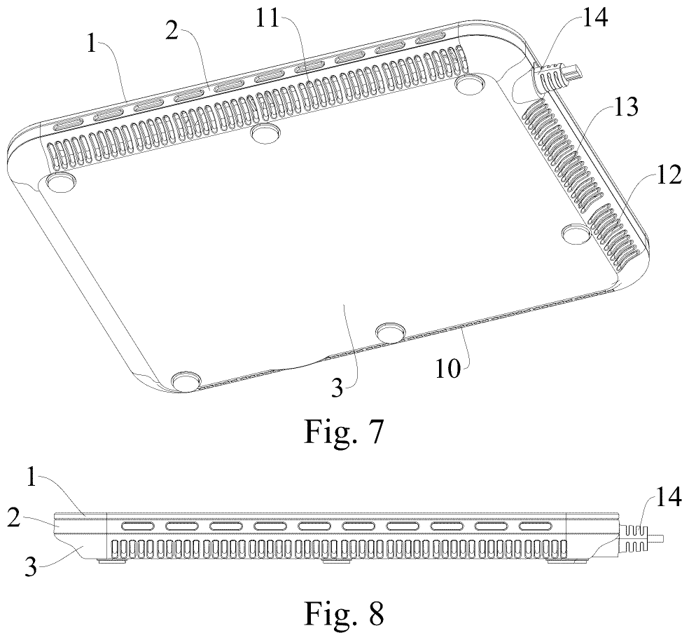

Specifically, referring to FIGS. 3 and 7, the vent opening on a sidewall of the bottom housing 3 includes a first air inlet 10 and a first air outlet 11, the first air inlet 10 is provided at a front side of the bottom housing 3, the first air outlet 11 is provided at a rear side of the bottom housing 3. In practice, the first fan 8 is provided close to the motherboard 5, and the first fan 8 is provided with two openings simultaneously, a first opening and a second opening, respectively. When the first fan 8 starts working, the first fan 8 is made to not only transport the air from the outside along the first opening and the bottom of the electromagnetic coil 6 all the way to the first air outlet 11, thereby continuously taking away the heat from the bottom of the electromagnetic coil 6 to achieve a cooling effect. Moreover, the first fan 8 may also transport the outside air along the second opening towards the heat dissipation sheet 7 and the upper surface of the motherboard 5, and then out of the first air outlet 11 to dissipate the heat of the motherboard 5. Additionally, the second fan 9 has an opening facing the electromagnetic coil 6, i.e., the first opening. When the second fan 9 is operating, outside air may also enter into the second fan 9 along the first air inlet 10. Under the action of the second fan 9, the air may be transported along the first opening and the bottom of the electromagnetic coil 6 all the way to the first air outlet 11, so as to achieve the cooling effect of the electromagnetic coil 6.

Specifically, referring to FIGS. 3 and 7, a right side of the bottom housing 3 is fixedly provided with a retainment plate 301 extending vertically upwards, the retainment plate 301 is close to the second fan 9, and the retainment plate 301 is extended from a sidewall of the bottom housing 3 to the first opening of the second fan 3 close thereto, so that the second fan 9 is positioned in the cold-air zone and the electromagnetic coil 6 is positioned in the hot-air zone. The vent opening is further provided with a second air inlet 12 and a second air outlet 13, both the second air inlet 12 and the second air outlet 13 are arranged back and forth along the right curved wall of the bottom housing 3, the retainment plate 301 is provided between the second air inlet 12 and the second air outlet 13, so that hot and cold air may be separated, the second air inlet 12 is positioned in the cold-air zone, and the second air outlet 13 is positioned in the hot-air zone. In practice, the air from the outside may enter into the second fan 9 via the second air inlet 12, and under the action of the second fan 9, the air may flow along the first opening, the bottom of the electromagnetic coil 6, and finally out of the first air outlet 11, thereby achieving heat dissipation of the electromagnetic coil 6. In addition, when the first fan 8 also works simultaneously and the air speed blown from the first fan 8 is greater than the air speed blown from the second fan 9, under the action of the first fan 8, the hot air at this moment may also flow out through the second air outlet 13, and the heat dissipation of the electromagnetic coils 6 may likewise be achieved.

The curved side wall of the bottom housing 3 is provided with a first air inlet 10, a first air outlet 11, a second air inlet 12, and a second air outlet 13, which allows for a smoother flow of airflow within the bottom housing 3, thereby resulting in a better cooling effect.

Specifically, as shown in FIGS. 3-4, the electromagnetic coil 6 is provided with a plurality of through-holes penetrating up and down around the periphery of the electromagnetic coil 6, and the bottom housing 3 is fixedly provided with a first threaded column 302 that may achieve a positioning fit with the through-holes, and the first threaded column 302 passes upwardly through the through-holes to realize a detachable connection with the electromagnetic coil 6. More specifically, the first threaded column 302 is provided with threaded holes internally, and the electromagnetic coil 6 is fixedly disposed on the bottom housing 3 by screws. The removable fixation facilitates the replacement of the electromagnetic coil 6.

Specifically, as shown in FIGS. 3-4, a plurality of second threaded columns 303 extending vertically upwards are fixedly provided in the bottom housing 3, the plurality of second threaded columns 303 are respectively wound around the side of the first fan 8 and the second fan 9, through-holes are respectively provided on the first fan 8 and the second fan 9 to achieve a positioning fit with the plurality of second threaded columns 303, and the first fan 8 and the second fan 9 are provided on the bottom housing 3 via screw positioning.

Specifically, as shown in FIG. 1, the motherboard 5 is fixedly disposed on the bottom housing 3 by screws, and the heat dissipation sheet 7 is fixedly disposed on the motherboard 5 by screws. In practice, part of the heat on the motherboard 5 is taken away directly through the first fan 8, and part of the heat may be transferred to the heat dissipation sheet 7 and then taken away through the first fan 8. Multi-channel heat dissipation is used to reduce the heat of the motherboard 5, which then enables the service life of the motherboard 5 to be guaranteed to a certain extent.

Specifically, referring to FIGS. 4-5, an inner periphery of the bottom housing 3 is provided with a plurality of positioning columns 304 extending vertically upwards, the positioning column 304 is provided with a stepped hole with an opening facing upwards, a side of the upper cover 2 facing the bottom housing 3 is provided with a plurality of columns 201, and the plurality of columns 201 is in interference fit with a plurality of the stepped holes so that the bottom housing 3 and the upper cover 2 are fixedly mounted. As shown in FIGS. 6-8, a top of the upper cover 2 is flattened and fixed with a front panel 1.

Specifically, referring to FIGS. 1-3, the bottom right corner of the bottom housing 3 is provided with a groove 305 penetrating from left to right, and a power line 14 is provided in the groove 305. In practice, the power line 14 is connected to the control board 4, the motherboard 5, the electromagnetic coil 6, and the two fans in the wiring to provide operating power.

Provided in the present embodiment is further an induction hob, referring to FIGS. 4-5, in which the induction hob includes an upper cover and a heat dissipation structure as mentioned above, and the bottom housing 3 is fixedly connected to the upper cover 2 through an interference fit between the positioning columns 304 and the stepped holes. Since the sidewall of the bottom housing 3 is a curved wall, the height of the bottom housing 3 is effectively reduced while ensuring that the ventilation area of the vent opening is not reduced. Moreover, the flat setting of the motherboard 5 and electromagnetic coil 6 in the bottom housing 3, as well as two fans positioned in the periphery of the electromagnetic coil 6, may effectively reduce the thickness of the bottom housing 3, which all enable the induction hob to achieve ultra-thin design, which is convenient for the user to carry around during outings, and greatly improves the competitiveness of the product.

The above described are preferred embodiments of the present disclosure. It should be noted that for those skilled in the art, a plurality of improvements and modifications may be made without departing from the principles of the present disclosure, which should also be considered as the scope of protection of the present disclosure.

1. A heat dissipation structure for induction hobs, comprising a bottom housing for induction hobs, wherein a sidewall of the bottom housing is gradually extended outwardly inclined and concave inwardly into a curved wall from bottom to top, the curved wall being provided with a plurality of vent openings;
wherein an interior of the bottom housing is flatly provided with a motherboard and an electromagnetic coil, at least two fans are provided on a side of the electromagnetic coil, all fans are provided spaced apart around the electromagnetic coil, and a side of the fans facing the electromagnetic coil is provided with a first opening for achieving heat dissipation of the electromagnetic coil; and
wherein the fans proximal to the motherboard are further provided with a second opening facing the motherboard for achieving heat dissipation of the motherboard.

2. The heat dissipation structure for induction hobs according to claim 1, wherein the motherboard is fixedly provided with a heat dissipation sheet arranged close to the second opening, and the vent opening is extended upwardly from a bottom of the curved wall to form a hole in a shape like a bar.

3. The heat dissipation structure for induction hobs according to claim 1, wherein an interior of the bottom housing is provided with a control board, the motherboard, and the electromagnetic coil arranged sequentially along a length direction thereof, the electromagnetic coil is provided with two fans adjacent thereto, two fans are configured to be a first fan and a second fan, a second space for mounting the second fan is provided at a corner of an inner side of the bottom housing, and a first space for mounting the first fan is provided between the control board and the electromagnetic coil.

4. The heat dissipation structure for induction hobs according to claim 3, wherein the bottom housing is fixedly provided with a first partition and a second partition extending vertically upwards, the first partition and the second partition divide an interior of the bottom housing into a cold-air zone and a hot-air zone, the first fan and the second fan are positioned in the cold-air zone, and the motherboard and the electromagnetic coil are positioned in the hot-air zone.

5. The heat dissipation structure for induction hobs according to claim 4, wherein the first partition is provided between the first fan and the second fan, the second partition is provided between the control board and the motherboard, a side of an upper cover for induction hobs facing the bottom housing is fixedly provided with a third partition extending vertically downwards, a position of the third partition corresponds to those of the first partition and the second partition, and a bottom surface of the third partition is abutted against a bottom surface of the first partition and a top surface of the second partition when the upper cover is snap-fitted to the bottom housing, so as to separate the cold-air zone and the hot-air zone.

6. The heat dissipation structure for induction hobs according to claim 1, wherein a clearance is provided between a bottom of the electromagnetic coil and an inner bottom surface of the bottom housing.

7. The heat dissipation structure for induction hobs according to claim 1, wherein the vent opening comprises a first air inlet and a first air outlet, the first air inlet is provided at a front sidewall of the bottom housing, the first air outlet is provided at a rear sidewall of the bottom housing, and both the first opening and the second opening are provided in a direction facing the first air outlet.

8. The heat dissipation structure for induction hobs according to claim 1, wherein a right sidewall and/or a left sidewall of the bottom housing is fixedly provided with a retainment plate extending vertically upwards, the vent opening is further provided with a second air inlet and a second air outlet, both the second air inlet and the second air outlet are provided on the right sidewall or the left sidewall of the bottom housing, the retainment plate is provided between the second air inlet and the second air outlet so as to divide an interior of the bottom housing into a cold-air zone and a hot-air zone, the second air inlet is positioned in the cold-air zone, and the second air outlet is positioned in the hot-air zone.

9. The heat dissipation structure for induction hobs according to claim 2, wherein a right sidewall and/or a left sidewall of the bottom housing is fixedly provided with a retainment plate extending vertically upwards, the vent opening is further provided with a second air inlet and a second air outlet, both the second air inlet and the second air outlet are provided on the right sidewall or the left sidewall of the bottom housing, the retainment plate is provided between the second air inlet and the second air outlet so as to divide an interior of the bottom housing into a cold-air zone and a hot-air zone, the second air inlet is positioned in the cold-air zone, and the second air outlet is positioned in the hot-air zone.

10. The heat dissipation structure for induction hobs according to claim 3, wherein a right sidewall and/or a left sidewall of the bottom housing is fixedly provided with a retainment plate extending vertically upwards, the vent opening is further provided with a second air inlet and a second air outlet, both the second air inlet and the second air outlet are provided on the right sidewall or the left sidewall of the bottom housing, the retainment plate is provided between the second air inlet and the second air outlet so as to divide an interior of the bottom housing into a cold-air zone and a hot-air zone, the second air inlet is positioned in the cold-air zone, and the second air outlet is positioned in the hot-air zone.

11. The heat dissipation structure for induction hobs according to claim 8, wherein the retainment plate is close to one of the fans, and the retainment plate is extended from a sidewall of the bottom housing to the first opening of the fan close to the retainment plate, so that the fan is positioned in the cold-air zone.

12. An induction hob, comprising an upper cover and a heat dissipation structure, wherein an inner periphery of a bottom housing is provided with a plurality of positioning columns extending vertically upwards, the positioning column is provided with a stepped hole with an opening facing upwards, a side of the upper cover facing the bottom housing is provided with a plurality of columns, and the plurality of columns is in interference fit with a plurality of the stepped holes;
wherein the heat dissipation structure comprises a bottom housing for induction hobs, a sidewall of the bottom housing is gradually extended outwardly inclined and concave inwardly into a curved wall from bottom to top, the curved wall being provided with a plurality of vent openings;
wherein an interior of the bottom housing is flatly provided with a motherboard and an electromagnetic coil, at least two fans are provided on a side of the electromagnetic coil, all fans are provided spaced apart around the electromagnetic coil, and a side of the fans facing the electromagnetic coil is provided with a first opening for achieving heat dissipation of the electromagnetic coil; and
wherein the fans proximal to the motherboard are further provided with a second opening facing the motherboard for achieving heat dissipation of the motherboard.

13. The induction hob according to claim 12, wherein the motherboard is fixedly provided with a heat dissipation sheet arranged close to the second opening, and the vent opening is extended upwardly from a bottom of the curved wall to form a hole in a shape like a bar.

14. The induction hob according to claim 12, wherein an interior of the bottom housing is provided with a control board, the motherboard, and the electromagnetic coil arranged sequentially along a length direction thereof, the electromagnetic coil is provided with two fans adjacent thereto, two fans are configured to be a first fan and a second fan, a second space for mounting the second fan is provided at a corner of an inner side of the bottom housing, and a first space for mounting the first fan is provided between the control board and the electromagnetic coil.

15. The induction hob according to claim 14, wherein the bottom housing is fixedly provided with a first partition and a second partition extending vertically upwards, the first partition and the second partition divide an interior of the bottom housing into a cold-air zone and a hot-air zone, the first fan and the second fan are positioned in the cold-air zone, and the motherboard and the electromagnetic coil are positioned in the hot-air zone.

16. The induction hob according to claim 15, wherein the first partition is provided between the first fan and the second fan, the second partition is provided between the control board and the motherboard,
a side of an upper cover for induction hobs facing the bottom housing is fixedly provided with a third partition extending vertically downwards, a position of the third partition corresponds to those of the first partition and the second partition, and a bottom surface of the third partition is abutted against a bottom surface of the first partition and a top surface of the second partition when the upper cover is snap-fitted to the bottom housing, so as to separate the cold-air zone and the hot-air zone.

17. The induction hob according to claim 12, wherein a clearance is provided between a bottom of the electromagnetic coil and an inner bottom surface of the bottom housing.

18. The induction hob according to claim 12, wherein the vent opening comprises a first air inlet and a first air outlet, the first air inlet is provided at a front sidewall of the bottom housing, the first air outlet is provided at a rear sidewall of the bottom housing, and both the first opening and the second opening are provided in a direction facing the first air outlet.

19. The induction hob according to claim 12, wherein a right sidewall and/or a left sidewall of the bottom housing is fixedly provided with a retainment plate extending vertically upwards, the vent opening is further provided with a second air inlet and a second air outlet, both the second air inlet and the second air outlet are provided on the right sidewall or the left sidewall of the bottom housing, the retainment plate is provided between the second air inlet and the second air outlet so as to divide an interior of the bottom housing into a cold-air zone and a hot-air zone, the second air inlet is positioned in the cold-air zone, and the second air outlet is positioned in the hot-air zone.

20. The induction hob according to claim 19, wherein the retainment plate is close to one of the fans, and the retainment plate is extended from a sidewall of the bottom housing to the first opening of the fan close to the retainment plate, so that the fan is positioned in the cold-air zone.
